(19) United States
(12) Patent Application Publication
(10) Pub. No.: US 2024/0135072 A1
(43) Pub. Date: Apr. 25, 2024

(54) Bottomhole Assembly Modeling

(71) Applicant: Halliburton Energy Services, Inc., Houston, TX (US)

(72) Inventors: Kaixiao Tian, Singapore (SG); Tingting Zeng, Houston, TX (US); Ketan C. Bhaidasna, Houston, TX (US); Julien Christian Marck, Houston, TX (US); Yang Liu, Singapore (SG)

(73) Assignee: Halliburton Energy Services, Inc., Houston, TX (US)

(21) Appl. No.: 17/969,545

(22) Filed: Oct. 18, 2022

(51) Int. Cl. G06F 30/28

(52) U.S. Cl. CPC G06F 30/28

(57) ABSTRACT

A method for forming a model of a bottom hole assembly (BHA) in a borehole, wherein the BHA is connected to a drill string. The method may further comprise segmenting the model into one or more segments and solving a multipoint boundary value problem (BVP) based at least in part on the one or more segments.

### BACKGROUND

The oil and gas industry may use boreholes as fluid conduits to access subterranean deposits of various fluids and minerals which may comprise hydrocarbons. There may be a direct correlation between the productivity of a borehole and the interfacial surface area through which the borehole intersects a target subterranean formation. For this reason, it may be economically desirable to increase the length of a drilled section within a target subterranean formation by means of extending a horizontal, slant-hole, or deviated borehole through the target subterranean formation. Additionally, horizontal, slant-hole, and deviated drilling techniques may be utilized in operational contexts where the surface location is laterally offset from the target subterranean formation such that the target subterranean formation may not be accessible by vertical drilling alone.

For directional drilling operations, it is important to evaluate the drilling tendency of a bottomhole assembly (BHA). Such evaluation relies on the computation of the response of the BHA, subject to gravity, weight-on-bit, actuation from a rotary steerable system (RSS) and constraint of the borehole geometry. The dynamic effect arising from the BHA rotation is neglected and thus the static BHA response may only need to be calculated. A linear beam characterization of the BHA is not sufficient for configurations such that the weight-on-bit is large, or the flexural rigidity is relatively small for certain segments. Additionally, due to the clearance between the BHA body and the borehole wall, the borehole contact configuration is a priori unknown. The nature of the contact has to be determined first and then solved quantitively. This condition further complicates the problem.

### BRIEF DESCRIPTION OF THE DRAWINGS

These drawings illustrate certain aspects of some examples of the present disclosure and should not be used to limit or define the disclosure.

FIG. 1 illustrates an example of a drilling system and operation;

FIG. 2 illustrates is a schematic view of an information handling system;

FIG. 3 illustrates another schematic view of and information handling system;

FIG. 4 illustrates a schematic view of a network;

FIGS. 5A-5E illustrates graphs of statics responses a bottom hole assembly (BHA) may undergo during a directional drilling operation;

FIG. 6 illustrates an example of an input grid for λ_{I};

FIG. 7 illustrates an example of an input grid for λ_{II};

FIG. 8 illustrates an example of an input grid for λ_{III};

FIG. 9 illustrates a collection of auxiliary problems together with proper boundary conditions defines a multipoint boundary value problem (multipoint BVP);

FIG. 10 illustrates a local Cartesian coordinate system; and

FIGS. 11A-11E illustrate graphs of an iterative approach to solving the BHA responses seen in FIGS. 5A-5E.

### DETAILED DESCRIPTION

This disclosure details methods and systems for computing a static response for a given bottom hole assembly (BHA) that may be converted into a multipoint boundary value problem (BVP). This may allow for the modeling of BHAs with considerations of the nonlinear effects, which may allow for a fast and robust evaluation of the BHA response irrespective of the tool configurations.

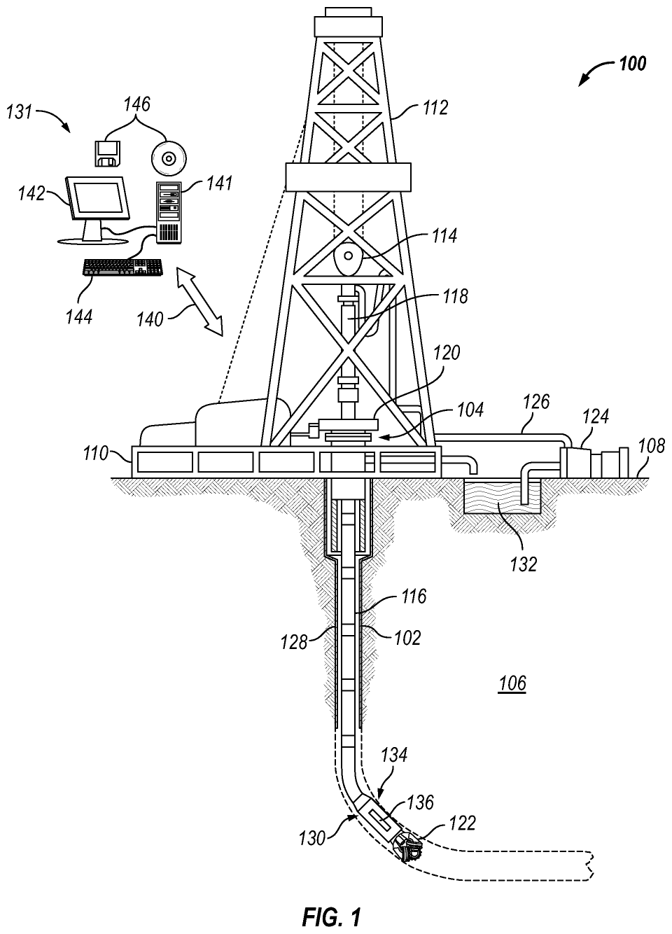

FIG. 1 illustrates an example of drilling system 100. As illustrated, borehole 102 may extend from a wellhead 104 into a subterranean formation 106 from a surface 108. Generally, borehole 102 may comprise horizontal, vertical, slanted, curved, and other types of borehole geometries and orientations. Borehole 102 may be cased or uncased. In examples, borehole 102 may comprise a metallic member. By way of example, the metallic member may be a casing, liner, tubing, or other elongated steel tubular disposed in borehole 102.

As illustrated, borehole 102 may extend through subterranean formation 106. As illustrated in FIG. 1, borehole 102 may extend generally vertically into the subterranean formation 106, however, borehole 102 may extend at an angle through subterranean formation 106, such as horizontal and slanted boreholes. For example, although FIG. 1 illustrates a vertical or low inclination angle well, high inclination angle or horizontal placement of the well and equipment may be possible. It should further be noted that while FIG. 1 generally depicts land-based operations, those skilled in the art may recognize that the principles described herein are equally applicable to subsea operations that employ floating or sea-based platforms and rigs, without departing from the scope of the disclosure.

As illustrated, a drilling platform 110 may support a derrick 112 having a traveling block 114 for raising and lowering drill string 116. Drill string 116 may comprise, but is not limited to, drill pipe and coiled tubing, as generally known to those skilled in the art. A kelly 118 may support drill string 116 as it may be lowered through a rotary table 120. A drill bit 122 may be attached to the distal end of drill string 116 and may be driven either by a downhole motor, a rotary steerable system (“RSS”), and/or via rotation of drill string 116 from surface 108. Without limitation, drill bit 122 may comprise, roller cone bits, PDC bits, natural diamond bits, any hole openers, reamers, coring bits, and the like. As drill bit 122 rotates, it may create and extend borehole 102 that penetrates various subterranean formations 106. A pump 124 may circulate drilling fluid through a feed pipe 126 through kelly 118, downhole through interior of drill string 116, through orifices in drill bit 122, back to surface 108 via annulus 128 surrounding drill string 116, and into a retention pit 132.

With continued reference to FIG. 1, drill string 116 may begin at wellhead 104 and may traverse borehole 102. Drill bit 122 may be attached to a distal end of drill string 116 and may be driven, for example, either by a downhole motor and/or via rotation of drill string 116 from surface 108. In a non-limiting example, the weight of drill string 116 and bottom hole assembly may be controlled and measured while drill bit 122 is disposed within borehole 102. In further examples, drill bit 122 may or may not be in contact with the bottom of borehole 102. Drill bit 122 may be allowed to contact the bottom of borehole 102 with varying amounts of weight applied to drill bit 122. The weight of drill string 116 may be measured at the surface of borehole 102 and may be referred to as the “hook load.” The difference in the hook load when drill bit 122 is suspended just above the bottom of borehole 102 and the hook load when drill bit 122 is in contact with the bottom of borehole 102 may be referred to as the weight-on-bit (“WOB”). Both the hook load and the weight-on-bit may be considered drilling parameters. In some examples the hook load may be measured by a hoisting system or a hook load sensor. In some examples, the hook load is measured at the surface by a sensor disposed at the surface of drilling system 100. Drill bit 122 may be a part of BHA 130 at the distal end of drill string 116. In some examples, BHA 130 may further comprise tools for directional drilling applications. In other examples, directional drilling tools may be disposed anywhere along the drill string assembly. In further examples, directional drilling tools may be disposed within the borehole using wireline, electric line, or slick line. As will be appreciated by those of ordinary skill in the art, BHA 130 may comprise directional drilling tools including but not limited to a measurement-while drilling (MWD) and/or logging-while drilling (LWD) system, magnetometers, accelerometers, agitators, bent subs, orienting subs, mud motors, rotary steerable systems (RSS), jars, vibration reduction tools, roller reamers, pad pushers, non-magnetic drilling collars, whipstocks, push-the-bit systems, point-the-bit systems, directional steering heads and other directional drilling tools.

Bottom hole assembly (BHA) 130 may comprise any number of tools, transmitters, and/or receivers to perform downhole measurement operations. In some scenarios, these downhole measurements produce drilling parameters which may be used to guide the drilling operation. For example, as illustrated in FIG. 1, BHA 130 may comprise a measurement assembly 134. It should be noted that measurement assembly 134 may make up at least a part of BHA 130. Without limitation, any number of different measurement assemblies, communication assemblies, battery assemblies, and/or the like may form BHA 130 with measurement assembly 134. Additionally, measurement assembly 134 may form BHA 130 itself. In examples, measurement assembly 134 may comprise at least one sensor 136, which may be disposed at the surface of measurement assembly 134. It should be noted that while FIG. 1 illustrates a single sensor 136, there may be any number of sensors disposed on or within measurement assembly 134. Without limitation, sensors may be referred to as a transceiver. Further, it should be noted that there may be any number of sensors disposed along BHA 130 at any degree from each other. In examples, sensors 136 may also comprise backing materials and matching layers. It should be noted that sensors 136 and assemblies housing sensors 136 may be removable and replaceable, for example, in the event of damage or failure.

Without limitation, BHA 130 may be connected to and/or controlled by information handling system 131, which may be disposed on surface 108. Without limitation, information handling system 131 may be disposed down hole in BHA 130. Processing of information recorded may occur down hole and/or on surface 108. Processing occurring downhole may be transmitted to surface 108 to be recorded, observed, and/or further analyzed. Additionally, information recorded on information handling system 131 that may be disposed down hole may be stored until BHA 130 may be brought to surface 108. In examples, information handling system 131 may communicate with BHA 130 through a communication line (not illustrated) disposed in (or on) drill string 116. In examples, wireless communication may be used to transmit information back and forth between information handling system 131 and BHA 130. Information handling system 131 may transmit information to BHA 130 and may receive as well as process information recorded by BHA 130. In examples, a downhole information handling system (not illustrated) may comprise, without limitation, a microprocessor or other suitable circuitry, for estimating, receiving, and processing signals from BHA 130. Downhole information handling system (not illustrated) may further comprise additional components, such as memory, input/output devices, interfaces, and the like. In examples, while not illustrated, BHA 130 may comprise one or more additional components, such as analog-to-digital converter, filter, and amplifier, among others, that may be used to process the measurements of BHA 130 before they may be transmitted to surface 108. Alternatively, raw measurements from BHA 130 may be transmitted to surface 108.

Any suitable technique may be used for transmitting signals from BHA 130 to surface 108, including, but not limited to, wired pipe telemetry, mud-pulse telemetry, acoustic telemetry, and electromagnetic telemetry. While not illustrated, BHA 130 may comprise a telemetry subassembly that may transmit telemetry data to surface 108. At surface 108, pressure sensors (not shown) may convert the pressure signal into electrical signals for a digitizer (not illustrated). The digitizer may supply a digital form of the telemetry signals to information handling system 131 via a communication link 140, which may be a wired or wireless link. The telemetry data may be analyzed and processed by information handling system 131.

As illustrated, communication link 140 (which may be wired or wireless, for example) may be provided that may transmit data from BHA 130 to an information handling system 131 at surface 108. Information handling system 131 may comprise a central processing unit 141, an output display 142, an input device 144 (i.e., other input devices.), and/or non-transitory computer-readable media 146 (e.g., optical disks, magnetic disks) that can store code representative of the methods described herein. In addition to, or in place of processing at surface 108, processing may occur downhole. As discussed below, methods may be utilized by information handling system 131 to facilitate maximizing the ROP of drilling system 100 while minimizing unplanned deviations from the planned well trajectory.

Information handling system 131 may comprise any instrumentality or aggregate of instrumentalities operable to compute, estimate, classify, process, transmit, receive, retrieve, originate, switch, store, display, manifest, detect, record, reproduce, handle, or utilize any form of information, intelligence, or data for business, scientific, control, or other purposes. For example, an information handling system 131 may be a personal computer, a network storage device, or any other suitable device and may vary in size, shape, performance, functionality, and price. Information handling system 131 may comprise random access memory (RAM), one or more processing resources such as a central processing unit 141 (CPU) or hardware or software control logic, ROM, and/or other types of nonvolatile memory. Additional components of the information handling system 131 may non-transitory computer-readable media 146, output devices 142, such as a video display, and one or more network ports for communication with external devices as well as an input device 144 (e.g., keyboard, mouse, etc.). Information handling system 131 may also comprise one or more buses operable to transmit communications between the various hardware components.

Alternatively, systems and methods of the present disclosure may be implemented, at least in part, with non-transitory computer-readable media. Non-transitory computer-readable media may comprise any instrumentality or aggregation of instrumentalities that may retain data and/or instructions for a period of time. Non-transitory computer-readable media may comprise, for example, storage media such as a direct access storage device (e.g., a hard disk drive or floppy disk drive), a sequential access storage device (e.g., a tape disk drive), compact disk, CD-ROM, DVD, RAM, ROM, electrically erasable programmable read-only memory (EEPROM), and/or flash memory; as well as communications media such wires, optical fibers, microwaves, radio waves, and other electromagnetic and/or optical carriers; and/or any combination of the foregoing.

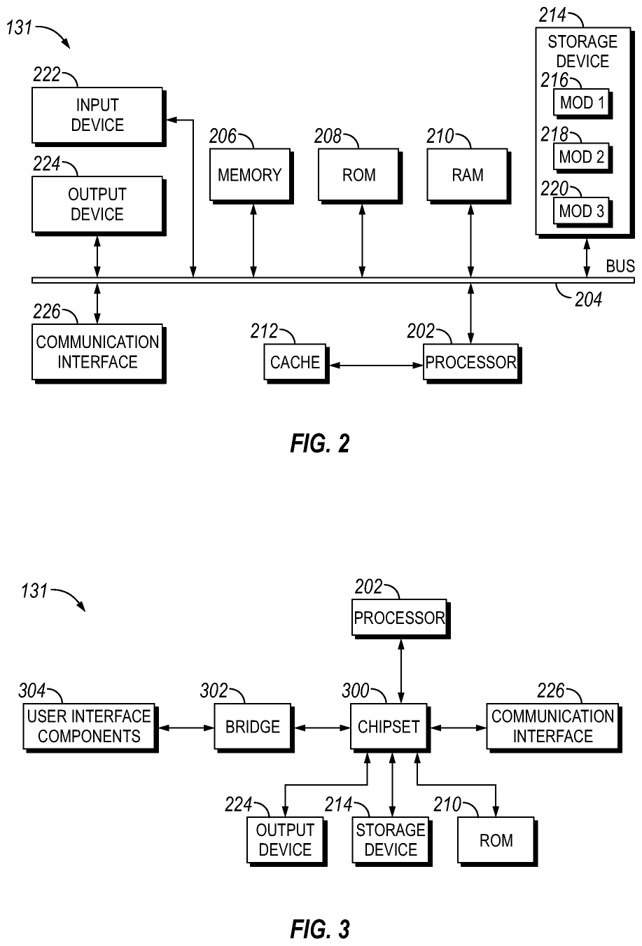

FIG. 2 illustrates an example information handling system 131 which may be employed to perform various steps, methods, and techniques disclosed herein. Persons of ordinary skill in the art will readily appreciate that other system examples are possible. As illustrated, information handling system 131 comprises a processing unit (CPU or processor) 202 and a system bus 204 that couples various system components including system memory 206 such as read only memory (ROM) 208 and random-access memory (RAM) 210 to processor 202. Processors disclosed herein may all be forms of this processor 202. Information handling system 131 may comprise a cache 212 of high-speed memory connected directly with, in close proximity to, or integrated as part of processor 202. Information handling system 131 copies data from memory 206 and/or storage device 214 to cache 212 for quick access by processor 202. In this way, cache 212 provides a performance boost that avoids processor 202 delays while waiting for data. These and other modules may control or be configured to control processor 202 to perform various operations or actions. Other system memory 206 may be available for use as well. Memory 206 may comprise multiple different types of memory with different performance characteristics. It may be appreciated that the disclosure may operate on information handling system 131 with more than one processor 202 or on a group or cluster of computing devices networked together to provide greater processing capability. Processor 202 may comprise any general-purpose processor and a hardware module or software module, such as first module 216, second module 218, and third module 220 stored in storage device 214, configured to control processor 202 as well as a special-purpose processor where software instructions are incorporated into processor 202. Processor 202 may be a self-contained computing system, containing multiple cores or processors, a bus, memory controller, cache, etc. A multi-core processor may be symmetric or asymmetric. Processor 202 may comprise multiple processors, such as a system having multiple, physically separate processors in different sockets, or a system having multiple processor cores on a single physical chip. Similarly, processor 202 may comprise multiple distributed processors located in multiple separate computing devices but working together such as via a communications network. Multiple processors or processor cores may share resources such as memory 206 or cache 212 or may operate using independent resources. Processor 202 may comprise one or more state machines, an application specific integrated circuit (ASIC), or a programmable gate array (PGA) including a field PGA (FPGA).

Each individual component discussed above may be coupled to system bus 204, which may connect each and every individual component to each other. System bus 204 may be any of several types of bus structures including a memory bus or memory controller, a peripheral bus, and a local bus using any of a variety of bus architectures. A basic input/output (BIOS) stored in ROM 208 or the like, may provide the basic routine that helps to transfer information between elements within information handling system 131, such as during start-up. Information handling system 131 further comprises storage devices 214 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. Storage device 214 may comprise software modules 216, 218, and 220 for controlling processor 202. Information handling system 131 may comprise other hardware or software modules. Storage device 214 is connected to the system bus 204 by a drive interface. The drives and the associated computer-readable storage devices provide nonvolatile storage of computer-readable instructions, data structures, program modules and other data for information handling system 131. In one aspect, a hardware module that performs a particular function comprises the software component stored in a tangible computer-readable storage device in connection with the necessary hardware components, such as processor 202, system bus 204, and so forth, to carry out a particular function. In another aspect, the system may use a processor and computer-readable storage device to store instructions which, when executed by the processor, cause the processor to perform operations, a method or other specific actions. The basic components and appropriate variations may be modified depending on the type of device, such as whether information handling system 131 is a small, handheld computing device, a desktop computer, or a computer server. When processor 202 executes instructions to perform “operations”, processor 202 may perform the operations directly and/or facilitate, direct, or cooperate with another device or component to perform the operations.

As illustrated, information handling system 131 employs storage device 214, which may be a hard disk or other types of computer-readable storage devices which may store data that are accessible by a computer, such as magnetic cassettes, flash memory cards, digital versatile disks (DVDs), cartridges, random access memories (RAMs) 210, read only memory (ROM) 208, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with information handling system 131, an input device 222 represents any number of input mechanisms, such as a microphone for speech, a touch-sensitive screen for gesture or graphical input, keyboard, mouse, motion input, speech and so forth. An output device 224 may also be one or more of a number of output mechanisms known to those of skill in the art. In some instances, multimodal systems enable a user to provide multiple types of input to communicate with information handling system 131. Communications interface 226 generally governs and manages the user input and system output. There is no restriction on operating on any particular hardware arrangement and therefore the basic hardware depicted may easily be substituted for improved hardware or firmware arrangements as they are developed.

As illustrated, each individual component describe above is depicted and disclosed as individual functional blocks. The functions these blocks represent may be provided through the use of either shared or dedicated hardware, including, but not limited to, hardware capable of executing software and hardware, such as a processor 202, that is purpose-built to operate as an equivalent to software executing on a general-purpose processor. For example, the functions of one or more processors presented in FIG. 2 may be provided by a single shared processor or multiple processors. (Use of the term “processor” should not be construed to refer exclusively to hardware capable of executing software.) Illustrative examples may comprise microprocessor and/or digital signal processor (DSP) hardware, read-only memory (ROM) 208 for storing software performing the operations described below, and random-access memory (RAM) 210 for storing results. Very large-scale integration (VLSI) hardware examples, as well as custom VLSI circuitry in combination with a general-purpose DSP circuit, may also be provided.

FIG. 3 illustrates an example information handling system 131 having a chipset architecture that may be used in executing the described method and generating and displaying a graphical user interface (GUI). Information handling system 131 is an example of computer hardware, software, and firmware that may be used to implement the disclosed technology. Information handling system 131 may comprise a processor 202, representative of any number of physically and/or logically distinct resources capable of executing software, firmware, and hardware configured to perform identified computations. Processor 202 may communicate with a chipset 300 that may control input to and output from processor 202. In this example, chipset 300 outputs information to output device 224, such as a display, and may read and write information to storage device 214, which may comprise, for example, magnetic media, and solid-state media. Chipset 300 may also read data from and write data to RAM 210. A bridge 302 for interfacing with a variety of user interface components 304 may be provided for interfacing with chipset 300. Such user interface components 304 may comprise a keyboard, a microphone, touch detection and processing circuitry, a pointing device, such as a mouse, and so on. In general, inputs to information handling system 131 may come from any of a variety of sources, machine generated and/or human generated.

Chipset 300 may also interface with one or more communication interfaces 226 that may have different physical interfaces. Such communication interfaces may comprise interfaces for wired and wireless local area networks, for broadband wireless networks, as well as personal area networks. Some applications of the methods for generating, displaying, and using the GUI disclosed herein may comprise receiving ordered datasets over the physical interface or be generated by the machine itself by processor 202 analyzing data stored in storage device 214 or RAM 210. Further, information handling system 131 receive inputs from a user via user interface components 304 and execute appropriate functions, such as browsing functions by interpreting these inputs using processor 202.

In examples, information handling system 131 may also comprise tangible and/or non-transitory computer-readable storage devices for carrying or having computer-executable instructions or data structures stored thereon. Such tangible computer-readable storage devices may be any available device that may be accessed by a general purpose or special purpose computer, including the functional design of any special purpose processor as described above. By way of example, and not limitation, such tangible computer-readable devices may comprise RAM, ROM, EEPROM, CD-ROM or other optical disk storage, magnetic disk storage or other magnetic storage devices, or any other device which may be used to carry or store program code in the form of computer-executable instructions, data structures, or processor chip design. When information or instructions are provided via a network, or another communications connection (either hardwired, wireless, or combination thereof), to a computer, the computer properly views the connection as a computer-readable medium. Thus, any such connection is properly termed a computer-readable medium. Combinations of the above should also be comprised within the scope of the computer-readable storage devices.

Computer-executable instructions comprise, for example, instructions and data which cause a general-purpose computer, special purpose computer, or special purpose processing device to perform a certain function or group of functions. Computer-executable instructions also comprise program modules that are executed by computers in stand-alone or network environments. Generally, program modules comprise routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

In additional examples, methods may be practiced in network computing environments with many types of computer system configurations, including personal computers, hand-held devices, multi-processor systems, microprocessor-based or programmable consumer electronics, network PCs, minicomputers, mainframe computers, and the like. Examples may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

During drilling operations, information handling system 131 may process different types of the real time data originated from varied sampling rates and various sources, such as diagnostics data, sensor measurements, operations data, and/or the like. These measurements from borehole 102, BHA 130, measurement assembly 134, and sensor 136 may allow for information handling system 131 to perform real-time health assessment of the drilling operation. Drilling tools and equipment may further comprise a variety of sensors which may be able to provide real-time measurements and data relevant to steering the borehole in adherence to a well plan. In some examples this drilling equipment may comprise drilling rigs, top drives, drilling tubulars, mud motors, gyroscopes, accelerometers, magnetometers, bent housing subs, directional steering heads, rotary steerable systems (“RSS”), whipstocks, push-the-bit systems, point-the-bit systems, and other directional drilling tools. In the context of drilling operations, “real-time,” may be construed as monitoring, gathering, assessing, and/or utilizing data contemporaneously with the execution of the drilling operation. Real-time operations may further comprise modifying the initial design or execution of the planned operation in order to modify a well plan of a drilling operation. In some examples, the modifications to the drilling operation may occur through automated or semi-automated processes. An example of an automated drilling process may comprise relaying or downlinking a set of operational commands (control commands) to an RSS in order to modify a drilling operation to achieve a certain objective. In other examples, operational commands (control commands) may be automatically relayed to the top drive. In other examples, the operational commands (control commands) may be relayed to the rig personnel for review prior to implementation. In some examples, drilling objectives may be incorporated into the drilling operation through minimization of a cost function, which will be discussed in further detail below.

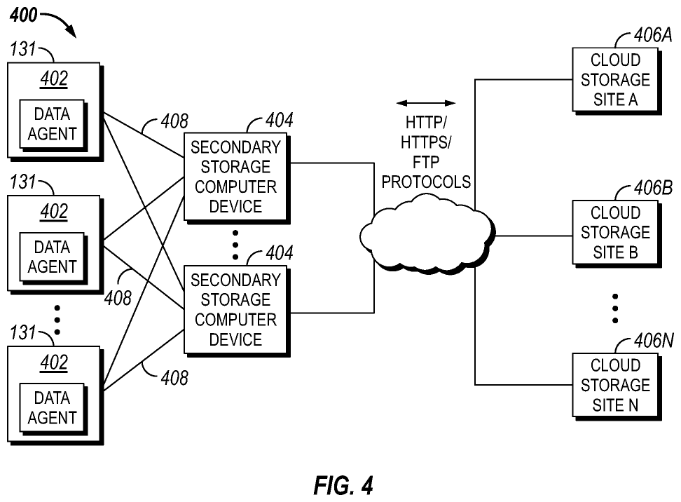

FIG. 4 illustrates an example of one arrangement of resources in a computing network 400 that may employ the processes and techniques described herein, although many others are of course possible. As noted above, an information handling system 131, as part of their function, may utilize data, which comprises files, directories, metadata (e.g., access control list (ACLS) creation/edit dates associated with the data, etc.), and other data objects. The data on the information handling system 131 is typically a primary copy (e.g., a production copy). During a copy, backup, archive or other storage operation, information handling system 131 may send a copy of some data objects (or some components thereof) to a secondary storage computing device 404 by utilizing one or more data agents 402.

A data agent 402 may be a desktop application, website application, or any software-based application that is run on information handling system 131. As illustrated, information handling system 131 may be disposed at any rig site (e.g., referring to FIG. 1) or repair and manufacturing center. The data agent may communicate with a secondary storage computing device 404 using communication protocol 408 in a wired or wireless system. The communication protocol 408 may function and operate as an input to a website application. In the website application, field data related to pre- and post-operations, generated DTCs, notes, and the like may be uploaded. Additionally, information handling system 131 may utilize communication protocol 408 to access processed measurements, operations with similar DTCs, troubleshooting findings, historical run data, and/or the like. This information is accessed from secondary storage computing device 404 by data agent 402, which is loaded on information handling system 131.

Secondary storage computing device 404 may operate and function to create secondary copies of primary data objects (or some components thereof) in various cloud storage sites 406A-N. Additionally, secondary storage computing device 404 may run determinative algorithms on data uploaded from one or more information handling systems 131, discussed further below. Communications between the secondary storage computing devices 404 and cloud storage sites 406A-N may utilize REST protocols (Representational state transfer interfaces) that satisfy basic C/R/U/D semantics (Create/Read/Update/Delete semantics), or other hypertext transfer protocol (“HTTP”)-based or file-transfer protocol (“FTP”)-based protocols (e.g., Simple Object Access Protocol).

In conjunction with creating secondary copies in cloud storage sites 406A-N, the secondary storage computing device 404 may also perform local content indexing and/or local object-level, sub-object-level or block-level deduplication when performing storage operations involving various cloud storage sites 406A-N. Cloud storage sites 406A-N may further record and maintain DTC code logs for each downhole operation or run, map DTC codes, store repair and maintenance data, store operational data, and/or provide outputs from determinative algorithms that are located in cloud storage sites 406A-N. In a non-limiting example, this type of network may be utilized as a platform to store, backup, analyze, import, and preform extract, transform and load (“ETL”) processes to the data gathered during a directional drilling operation.

For directional drilling operations, drilling tendency of a bottomhole assembly (BHA) 130 (e.g., referring to FIG. 1) may be evaluated using the methods and systems described above.

Such evaluations may rely on the computation of the response of BHA 130, subject to gravity, weight-on-bit, actuation from a rotary steerable system (RSS), and/or constraint of the borehole geometry. Thus, drilling tendency depicts the instantaneous borehole propagation direction at drill bit 122 (e.g., referring to FIG. 1). For a two-dimensional (2D) case within a vertical plane, if the drilling tendency is zero, BHA 130 may be maintaining the current curvature of borehole 102 (e.g., referring to FIG. 1). If the drilling tendency is positive, borehole 102 may be “building” in inclination. If the drilling tendency is negative, borehole 102 may be “dropping” in inclination. For the “turning” in the azimuth plane, the drilling tendency has a similar physical meaning. Instead, it describes if drill bit 122 may be (e.g., referring to FIG. 1) turning left or right. Practically, the term “drilling tendency” may comprise both 2D effects. The dynamic effect arising from rotation of BHA 130 may be neglected and only static responses of BHA 130 may be computed. However, for a static calculation, a linear beam characterization of BHA 130 may not be sufficient for configurations in which the weight-on-bit is large, or the flexural rigidity is relatively small for certain segment(s). Methods and systems discussed below may comprise a semi-analytical framework to model BHAs 130 with considerations of the nonlinear effects, which may allow for a fast and robust evaluation of the responses from BHA 130 irrespective of the configurations of BHA 130.

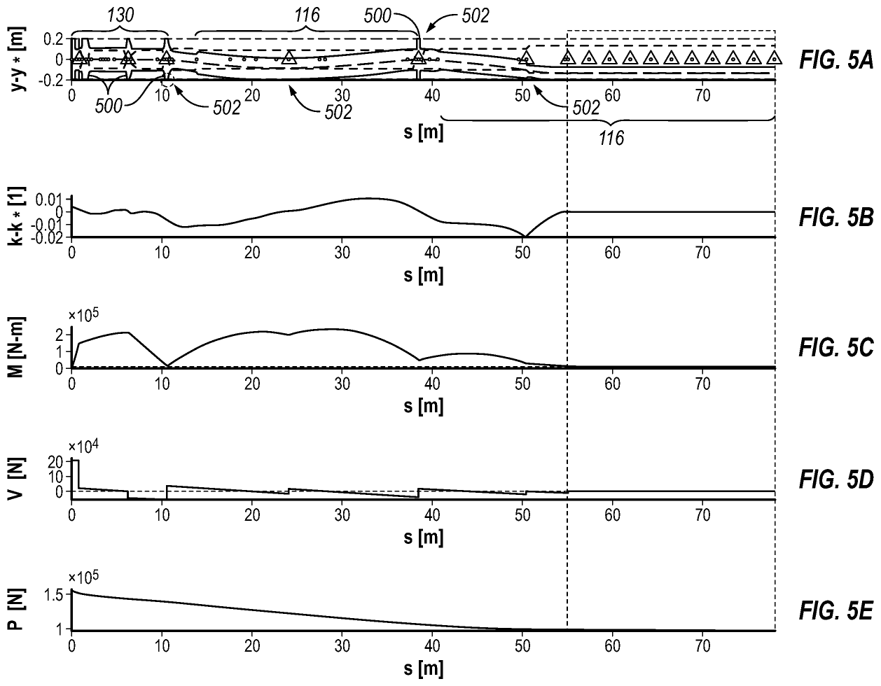

FIGS. 5A-5E are graphs illustrating statics responses a BHA 130 (e.g., referring to FIG. 1) may undergo during a directional drilling operation. Specifically, FIG. 5A illustrates a deformed BHA profile and the relative deflection of a BHA axis of rotation from a centerline of borehole 102. FIG. 5B illustrates a relative slope of the BHA axis of rotation compared to the slope of the centerline of borehole 102. FIG. 5C illustrates a bending moment, FIG. 5D illustrates shear force, and FIG. 5E illustrates a longitudinal (i.e., tangent to the deformed BHA axis of rotation) loading of BHA 130 when neglecting the longitudinal stiffness and frictional effects at a contact point between BHA 130 and borehole 102. As illustrated, BHA 130 may be connected to a drill string 116 and both BHA 130 and drill string 116 may be centered in borehole 102 by one or more stabilizers 500. Stabilizers 500 and areas in which drill string 116 contacts borehole 102 may be identified as contact points 502. In the graphs of FIGS. 5A-5E, a stabilizer 500 is defined as a small plateau in the deformed or undeformed BHA profile (i.e., FIG. 5A is the deformed BHA profile). The plateau refers to the positive jump of the BHA OD—a constant BHA OD—a negative jump of the BHA OD. Note that a stabilizer 500 is depicted as a plateau in FIG. 5A, yet a plateau is not necessarily a stabilizer 500. The user should provide the position of stabilizer 500 so that a plateau may be identified as a stabilizer 500, which may help in the computation of a static response of BHA 130. Computation of the static response for a given BHA 130 may be converted into a multipoint boundary value problem (BVP). Each sub-segment within a BHA segment with constant mechanical properties is subject to an auxiliary problem governed by a nonlinear beam equation with two boundary conditions. In examples, the boundary conditions at the nodes delimiting the sub-segment, depend on a continuity condition (i.e., where there is no contact and/or actuation between BHA 130 and borehole 102), external loading (i.e., actuation, weight-on-bit, etc.), or confines of borehole 102 imposed on BHA 130. The framework proposed in this disclosure systematically set up the appropriate multipoint BVP to solve the BHA response.

A BVP may comprise a number of inputs. As an input, mechanical properties are defined for each segment of BHA 130 that may be of interest. A segment of interest may be a segment chosen by a user in which to evaluate a shear force, bending moment, or other responses at a point within the segment of interest. Generally, a segment that comprises drill bit 122 (e.g., referring to FIG. 1) is a first segment of interest as the shear force at drill bit 122 and relative slope at drill bit 122 are used to estimate the drilling tendency of drilling system 100 (e.g., referring to FIG. 1). For each segment, the following properties may be considered a constant, segment length L, inner and outer diameters ID/OD, Young's modulus E, and submerged specific weight w. The level of discretization may be denoted by the distances λ between two neighboring nodes delimiting a segment.

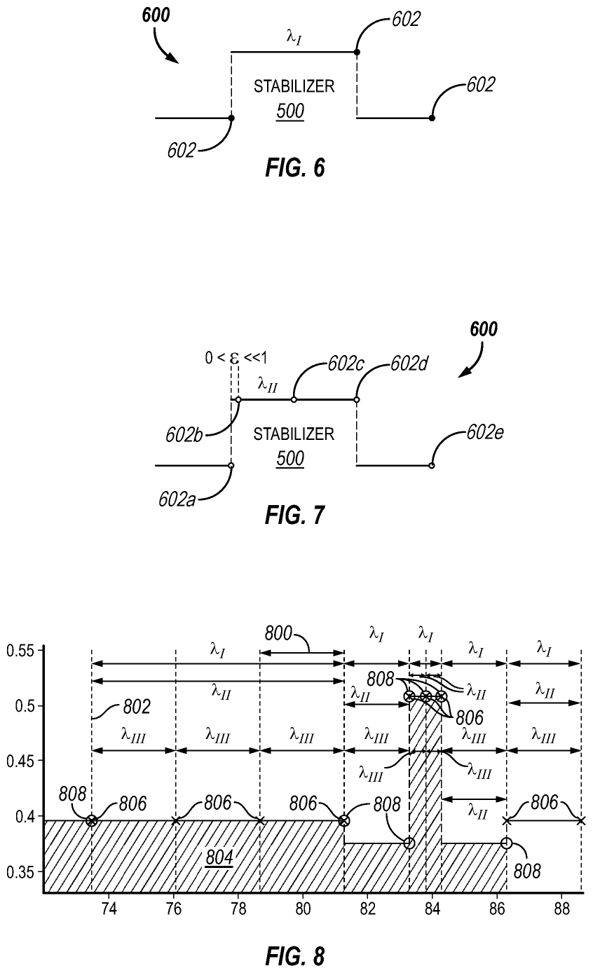

As illustrated in FIG. 6, an input grid 600 is denoted as λ_{I}. Input grid 600 may be utilized to determine where, or if, a contact point 502 (e.g., referring to FIG. 5) may exist. For example, input grid 600, λ_{I}, may comprise one or more points 602. These points may be “candidates” for actual contact points 502. The greater the number of points 602, the finer the resulting input grid 600 may be. As illustrated, FIG. 7 comprises more points 602a-602e, than FIG. 6, resulting in grid λ_{II}. In FIG. 7, there are at least three points 602b-602d for each stabilizer 500. Each point 602b-602d may represent a specific point of stabilizer 500. For example, a left corner, a mid-point, and/or a right corner. These “points added” may be candidates for contact points 502. A candidate may be identified as a contact point 502 after an iterative process, described below, determines point 602b-602d is in contact with borehole 102. Each stabilizer 500 may be characterized by segments. The segments, shown in FIG. 7 may be a length of ϵ (ϵ is a small positive number) and two with similar lengths. For example, FIG. 7 comprises points 602a-602e. A segment length may be defined as the length from 602a to 602d. This length may be refined by decomposing the length into 3 smaller segments. A first segment may be the length from 602b to 602a (i.e., ϵ), the second segment may be the length from 602b to 602c, and the third segment may be the length from 602c to 602d. Grid λ_{II} may be further discretized into a finer segment of as illustrated in FIG. 8.

FIG. 8 illustrates a graph in which each segment 800 of λ_{III} corresponds to an auxiliary problem. Segments 800 are delimited by boundaries 802 (i.e., vertical dashed lines). The outermost intersection between boundaries 802 and BHA profile 804 is denoted as node 806. Nodes 806 are actual points on the surface of BHA 130 that are in contact with at least a part of borehole 102 (e.g., referring to FIG. 1) if BHA 130 contacts with borehole 102 at this stabilizer. Physically, each segment 800 comprises constant mechanical properties. Additionally, it is ensured that contact may only occur at nodes 806 of such a segment 800 (this is the BVP segment). Contact is identified in FIG. 8 at nodes 806. As illustrated in FIG. 8, nodes 806 are associated with BVP segment λ_{III}, while nodes 808 are associated with BVP segment λ_{II}. Therefore, there are more nodes 806 than nodes 808. In examples, nodes 806 may be comprise of nodes 808 and newly added points (for finer grid). Thus, nodes 806 may be generated by further discretizing the segments delimited by nodes 808. As nodes 808 are comprised within nodes 806, both nodes 806 and 808 may be disposed at the same location. Without limitation, the length of a BVP segment λ_{III} may be controlled to ensure a balance between numerical accuracy and computational speed. An auxiliary problem is defined as solving for the mechanical response of a BVP segment λ_{III} where deformation within BVP segment λ_{III} is governed by a nonlinear beam equation and two boundary conditions imposed at both ends of the BVP segment λ_{III}.

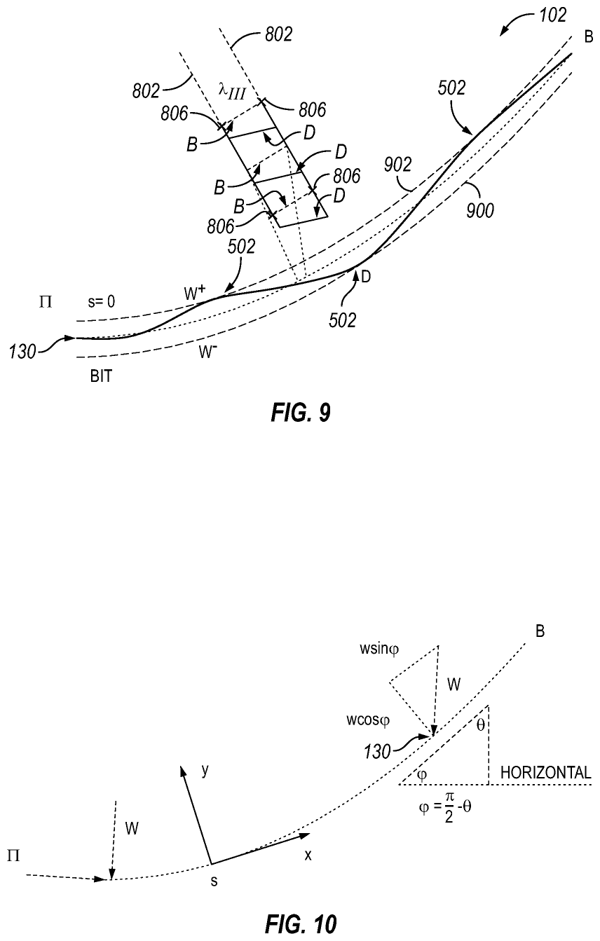

FIG. 9 illustrates a collection of auxiliary problems together with proper boundary conditions which defines a multipoint boundary value problem (multipoint BVP). The multipoint BVP is solved at boundaries 802 corresponding to λ_{III} in the undeformed configuration of BHA 130, which are discrete numerical solution defined at nodes 806. Boundaries 802 here refer to both end points of segment λ_{III}. Generally, when solving an auxiliary problem, a solution may be found at the end point locations (i.e., boundaries 802) of segment 800 and some internal points within segment 800 (e.g., referring to FIG. 8). However, as λ_{III} is set appropriately small, the auxiliary problem is solved at locations 802, the ends of segment 800. Solving the discrete number solution may allow for another grid λ_{IV} to be set up so that solutions at λ_{III} are interpolated to a new grid. Typically, grid is evenly spaced. For each auxiliary problem, solving a multipoint BVP (MBVP) may be performed in two orthogonal planes, an inclination plane and an azimuth plane. The independent responses in both planes are combined to form a 3D response. To this end, the solutions may be interpolated to the same uniform grid λ_{IV} (i.e., new grid), such that at a given node delimiting grid λ_{IV}, there exist independent planar solutions, which may be combined to form the 3D response. This grid λ_{IV} facilitates the composition of independent solutions for two dimensional (2D) BHA responses into a three-dimensional (3D) BHA response.

With continued reference to FIG. 9, it may be assumed that BHA centerline D, post-deformation, is a small perturbation of the borehole centerline B. This assumption generally holds true due to the existence of stabilizers 500 (e.g., referring to FIG. 5). This may allow a common curvilinear coordinate s to be used in the descriptions of D and B. In FIG. 10, a local Cartesian coordinate system xoy is defined for the description of the tangential and transversal direction specific to a given s. By definition, s=0 at drill bit 122 (e.g., referring to FIG. 1) where a weight-on-bit no is applied with its direction assumed to be the local tangential of B. The borehole geometry may be represented by the curve B and the cross-section shape varying with s. For the 2D representation in FIG. 9, curves W⁺ and W⁻ represent the boundaries of D due to the borehole's constraint on the deformation of BHA 130. Typically, the deformation offsets with respect to D are of the order of 1 mm. As illustrated, curve D may be in touch with curve B via point or line contact resulting in a reaction force orthogonal to D. In the Signorini Contact Law, for any contact, there may exist a contact force perpendicular to the contact plane, this is referred to as the reaction force. Additionally, a frictional force may exist at the contact as well. In examples, the frictional force may be correlated to the aforementioned reaction force with a friction coefficient. The directional of the frictional force is perpendicular to that of the reaction force. Using a segment of D, an auxiliary problem may be defined, as described above, corresponding to the grid system λ_{III} in FIG. 8. Other vectors and measurement angles may also be found using the variables from λ_{III}. For examples, FIG. 10 may utilize variables from λ_{III} to find inclination angle Θ and its complementary angle φ (namely slope). Accordingly, the approximated tangential and transverse gravity loading for BHA 130 are wsinφ and wcosφ, respectively. The variables in FIGS. 9 and 10 may be utilized to solve an auxiliary problem.

An auxiliary problem may be defined to find the response of a segment of BHA 130 (e.g., referring to FIG. 5) with its two ends subject to certain boundary conditions, in connection with another similarly defined auxiliary problem. Using Equations (1) and (2), seen below:

k\tilde{y}⁽⁴⁾+Π(\tilde{y}″+κ)+w cos ω̅=0 (1)

Π′+k\tilde{y}′″(\tilde{y}″+κ)+w sin ω̅=0 (2)

an auxiliary problem may be solved, where k is the segment's flexural rigidity and all derivatives are taken with respect to s. Variables may comprise deflection y represented as Y+\tilde{y}, slope y′ represented as ω̅+\tilde{y}′, a bending moment represented ask (κ+\tilde{y}″), a shear force represented as k\tilde{y}′″ and the longitudinal force is denoted as Π. Parameters Y, ω̅ and κ are the deflections, slope and curvature of the borehole centerline. Thus, \tilde{y} and its derivatives describe the perturbation from the constant curvature solution (BHA response when the deformed BHA centerline is strictly of constant curvature κ). Equation (2) captures the variation of the longitudinal force H within BHA 130, namely the nonlinear weight-on-bit (WOB) effect.

The aforementioned boundary conditions may comprise but are not limited to a continuity condition for an internal point, an imposed constrain in deflection, due to borehole constraint at point contact and/or line contact, an imposed jump in slope due to a point-the-bit actuation (RSS or mud motor), an imposed constraint in curvature due to line contact, and/or a jump in shear force due to push-the-bit RSS, which is mathematically shown as:

V=ky′″ (3)

The multipoint BVP may be solved by minimizing the residuals related to the boundary conditions. The solution of the multipoint BVP is the static BHA response corresponding to gravity, actuation, and the deflections of BHA 130 (e.g., referring to FIG. 1) at the locations of stabilizers 500 (e.g., referring to FIG. 5).

Referring back to FIG. 9, any part of BHA 130 may be in contact with borehole 102, a contact pattern may be determined. For each contact point 502 that BHA 130 has, an s coordinate may be found and which side of borehole 102 the contact is taking place (i.e., equivalent to the deflection value y at the contact) is found. At a potential contact point 502, the reaction force ΔV corresponding to the contact between BHA 130 and borehole 102 may be evaluated as the jump in shear force. Additionally, the clearance between BHA 130 and borehole 102 may be determined by the offset between curves D (computed for a tentative contact pattern) and W⁺ (or W⁻) (predefined as the borehole geometry). For a two-dimensional (2D) view, the clearance may be characterized by a pair of distances, between BHA 130 and two borehole walls. For example, at any location withing borehole 102, a first distance may be between BHA 130 and lower borehole wall 900 or upper borehole wall 902. Likewise, a second distance may be the distance between BHA 130 and lower borehole wall 900 or upper borehole wall 902, which ever distance is not the first distance. The first distance and the second distance may be utilized in a complementarity condition.

The complementarity condition is derived from the Signorini's contact law, which states that the magnitude of the contact force is strictly zero only when there is no contact (if there is contact, the absolute value of the reaction force is either zero or nonzero) and that the contact force is always pointing from borehole 102 to BHA 130 (e.g., referring to FIG. 1). Additionally, the complementarity condition is denoted by the reaction force as F. The reaction force which is positive if it is pointing upward and negative if it is pointing downward. As shown in Equations (4) & (5), seen below, the sign convention is illustrated in the inclination plane, and may be extended to the azimuth plane. Denote the difference between an outer diameter of BHA 130 and borehole diameter as 2γ, where:

−γ≤\tilde{y}≤γ (4)

The complementarity condition may be written as follows:

$$\{ \begin{matrix}F \geq 0 , & \tilde{y} = - γ \\ F = 0 , & - γ < \tilde{y} < γ \\ F \leq 0 , & \tilde{y} = γ\end{matrix} \qquad ( 5 )$$

As such, the pair of distances and the reaction force form a mixed complementarity problem (MCP), which may be solved via an optimization approach

There are two properties arising from the physics that dictate the choice of solver pertaining to the MCP. The first is the deflection y at one contact point only influences the y-F relationship for nearby contact points. Mathematically, this means the Jacobian matrix:

d\vec{F}/d\vec{y} (6)

is a banded sparse matrix, in which, at all the contact points, vector \vec{y} collects deflections, and vector \vec{F} collects reaction forces. Therefore, instead of more general, fixed points methods, a Newton-type solution is selected to take advantage of the sparse Jacobian matrix to achieve fast convergence. The second property is the reaction forces F, are monotonical with respect to the deflection y. Mathematically it results in a positive-definite Jacobian matrix, indicating a globally unique solution to the problem. Therefore, there is no need for globally convergent methods, which are more computationally expensive. For example, in a contact problem for stabilizers 500 (e.g., referring to FIG. 5), the quantities solved for are deflections at stabilizers 500. As there may exist a gap between the outer diameter stabilizer 500 and lower borehole wall 900 or upper borehole wall 902, the deflection of BHA 130 at stabilizer 500 may be unknown beforehand. It should be noted that if there is no gap between the outer dimension of stabilizer 500 and lower borehole wall 900 or upper borehole wall 902, the deflection of BHA 130 at stabilizer 500 may be known, as the centerline of BHA 130 may coincide with that of borehole 102 at this location (i.e., there is no need for the contact problem).

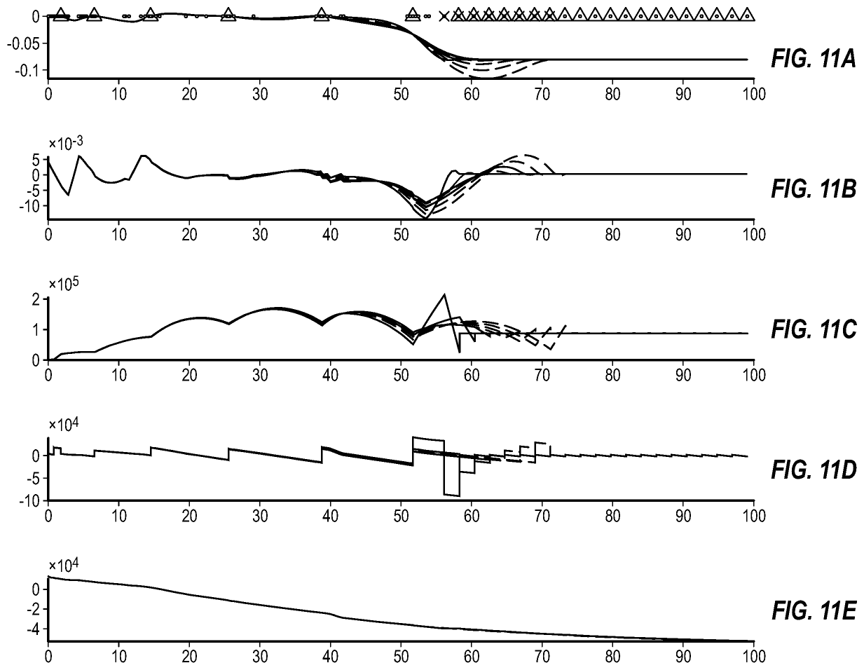

Considering the above, the solver chosen, a Levenberg-Marquardt Mixed Complementarity Problem (LMMCP), is chosen where the Fischer-Burmeister function is used as the merit function for fast convergence. FIGS. 11A-11E are graphs of a contact pattern for FIGS. 5A-5E that may be computed iteratively until a final state is reached where BHA 130 stays within borehole 102 (e.g., referring to FIG. 9) and the beam response satisfies the complementarity condition globally. The iterative approach may be utilized to determine a tangency point. A tangency point is a starting point of the line contact (i.e., a contact point 502). In examples, iteration may be utilized on less restrictive borehole geometry (i.e., varying curvatures). In examples, iteration may be utilized to solve deflections of BHA 130 (e.g., referring to FIG. 1) at all contact points 502.

The above method may be used to characterize certain point-the-bit rotary steerable systems as a nested beam model. An addition step may be performed prior to the treatment of the mixed complementarity problem (MCP). As noted above, if there is a single contact between BHA 130 and borehole 102 a MCP may be performed. When a beam (i.e., BHA 130) is inserted into a conduit, in a 2D setup, the beam may be in contact with either upper or lower wall (i.e., borehole 102). Effectively it is two complementarity problems coupled together, which creates a mixed complementarity problem. The additional step may define a list of interaction points where the housing (the outer beam) is in contact with the shaft (the inner beam). At the interaction points, the offsets between the deflections of the outer and inner beam are zero or constant. The constant is known and adjustable according to the design of a given point-the-bit RSS (i.e., BHA 130). To reach a physically reasonable result, a nonlinear least square algorithm may be used to ensure the reaction forces for the outer/inner beams are equal in magnitude and opposite in direction at the interaction nodes. The optimization variable is chosen as a vector that contains all deflections \tilde{y} at the interaction nodes (for either outer or inner beam). A cost function is chosen as the vector that contains the summations of all corresponding beam/beam reaction forces. In the least square algorithm, the reaction force varying with \tilde{y} may be determined using the disclosed method in the main embodiment.

The proposed methods and systems are an improvement over current technology. Specifically, current technology utilizes a Euler-Bernoulli beam equation with buckling to characterize a deflection in a bottom hole assembly (BHA). This creates issues as the Euler-Bernoulli beam equation assumes the longitudinal force within the BHA is constant and equal to the weight-on-bit, which is unrealistic. Additionally, gravity components (longitudinal gsinφ and transverse gcosφ, φ being the slope of the deformed BHA— approximately equal to the slope of the borehole in this problem) are constant and not varying, which is inaccurate, and the Euler-Bernoulli beam equation provides an unrealistic response at the BHA tail due to the absence of line contact in the formulation. Eventually, these simplifications in the current technology give a relatively inaccurate results for the BHA response, affecting the accuracy of the drilling tendency prediction.

The methods and systems described above are improvements over the use of Euler-Bernoulli beam equation. Specifically, the methods and systems take into account gravity distribution, which has been properly accounted for. Additionally, transmission of the longitudinal load within the BHA and a more realistic response at the tail of the BHA have been captured. With these, the overall BHA response is evaluated more accurately, resulting in a better estimation of the drilling tendency. Additionally, the methods and systems may predict the (static) BHA response more accurately for cases where the nonlinear effect associated with BHA deformation cannot be neglected. Systematically solve the nonlinear mixed complementarity problem (MCP) related to the BHA/borehole point contacts using optimization. The line contact is solved by approximating it with a series of point contacts while its contact configuration is determined analytically. The proposed framework may be used to model different BHA actuation mechanisms such as a point-the-bit RSS (rotary steerable system) where a shaft nests in a housing. The results from the proposed method also provide answers in a few seconds vs. a few hours (which is normal time frame for using a commercial finite element package), while yielding results of similar accuracy. Furthermore, the framework proposed may be extended to model more complex components in the BHA such as point-the-bit RSS. With current technology, analyses for BHAs with such components may only be performed with simplified analytical model or FEA study that may take a long computation time.

The systems and methods may comprise any of the various features disclosed herein, including one or more of the following statements. The systems and methods may comprise any of the various features disclosed herein, including one or more of the following statements.

Statement 1: A method may comprise forming a model of a bottom hole assembly (BHA) in a borehole, wherein the BHA is connected to a drill string. The method may further comprise segmenting the model into one or more segments and solving a multipoint boundary value problem (BVP) based at least in part on the one or more segments.

Statement 2: The method of statement 1, wherein the BVP is a static response of the BHA.

Statement 3: The method of any previous statement 1 or 2, wherein each of the one or more segments has a constant mechanical property.

Statement 4: The method of statement 2, further comprising solving an auxiliary problem for each of the one or more segments using a nonlinear beam equation with two boundary conditions.

Statement 5: The method of statement 4, wherein the two boundary conditions are external loading or confines of the borehole.

Statement 6: The method of statement 5, wherein the external loading is an actuation or a weight-on-bit.

Statement 7: The method of any previous statements 1, 2 or 3, further comprising determining a first distance from the BHA to a first borehole wall of the borehole for one of the one or more segments.

Statement 8: The method of statement 7, further comprising determining a first reaction force for the first distance.

Statement 9: The method of statement 8, further comprising solving a mixed complementarity problem (MCP) based at least in part on the first distance, the first reaction force, and a second distance from the BHA to a second borehole wall.

Statement 10: The method of statement 9, wherein the MCP is solved using a Jacobian matrix.

Statement 11: The method of statement 9, wherein the MCP is solved using a Levenberg-Marquardt Mixed Complementarity Problem (LMMCP).

Statement 12: A non-transitory storage computer-readable medium storing one or more instructions that, when executed by a processor, cause the processor to form a model of a bottom hole assembly (BHA) in a borehole, wherein the BHA is connected to a drill string. The one or more instructions, that when executed by the processor, further cause the processor to segment the model into one or more segments and solve a multipoint boundary value problem (BVP) based at least in part on the one or more segments.

Statement 13: The non-transitory storage computer-readable medium of statement 12, wherein the BVP is a static response of the BHA.

Statement 14: The non-transitory storage computer-readable medium of any previous statements 12 or 13, wherein each of the one or more segments has a constant mechanical property.

Statement 15: The non-transitory storage computer-readable medium of statement 14, wherein the one or more instructions, that when executed by the processor, further cause the processor to solve an auxiliary problem for each of the one or more segments using a nonlinear beam equation with two boundary conditions.

Statement 16: The non-transitory storage computer-readable medium of statement 15, wherein the two boundary conditions are external loading or confines of the borehole.

Statement 17: The non-transitory storage computer-readable medium of statement 16, wherein the external loading is an actuation or a weight-on-bit.

Statement 18: The non-transitory storage computer-readable medium of any previous statements 12, 13, or 14, wherein the one or more instructions, that when executed by the processor, further cause the processor to solve determine a first distance from the BHA to a first borehole wall of the borehole for one of the one or more segments, determine a first reaction force for the first distance, and solve a mixed complementarity problem (MCP) based at least in part on the first distance, the first reaction force, and a second distance from the BHA to a second borehole wall.

Statement 19: The non-transitory storage computer-readable medium of statement 18, wherein the MCP is solved using a Jacobian matrix.

Statement 20: The non-transitory storage computer-readable medium of statement 18, wherein the MCP is solved using a Levenberg-Marquardt Mixed Complementarity Problem (LMMCP).

Although the present disclosure and its advantages have been described in detail, it should be understood that various changes, substitutions and alterations may be made herein without departing from the spirit and scope of the disclosure as defined by the appended claims. The preceding description provides various examples of the systems and methods of use disclosed herein which may contain different method steps and alternative combinations of components. It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the element that it introduces.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any comprised range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

What is claimed is:

1. A method comprising:
forming a model of a bottom hole assembly (BHA) in a borehole, wherein the BHA is connected to a drill string;
segmenting the model into one or more segments; and
solving a multipoint boundary value problem (BVP) based at least in part on the one or more segments.

2. The method of claim 1, wherein the BVP is a static response of the BHA.

3. The method of claim 1, wherein each of the one or more segments has a constant mechanical property.

4. The method of claim 2, further comprising solving an auxiliary problem for each of the one or more segments using a nonlinear beam equation with two boundary conditions.

5. The method of claim 4, wherein the two boundary conditions are external loading or confines of the borehole.

6. The method of claim 5, wherein the external loading is an actuation or a weight-on-bit.

7. The method of claim 1, further comprising determining a first distance from the BHA to a first borehole wall of the borehole for one of the one or more segments.

8. The method of claim 7, further comprising determining a first reaction force for the first distance.

9. The method of claim 8, further comprising solving a mixed complementarity problem (MCP) based at least in part on the first distance, the first reaction force, and a second distance from the BHA to a second borehole wall.

10. The method of claim 9, wherein the MCP is solved using a Jacobian matrix.

11. The method of claim 9, wherein the MCP is solved using a Levenberg-Marquardt Mixed Complementarity Problem (LMMCP).

12. A non-transitory storage computer-readable medium storing one or more instructions that, when executed by a processor, cause the processor to:
form a model of a bottom hole assembly (BHA) in a borehole, wherein the BHA is connected to a drill string;
segment the model into one or more segments; and
solve a multipoint boundary value problem (BVP) based at least in part on the one or more segments.

13. The non-transitory storage computer-readable medium of claim 12, wherein the BVP is a static response of the BHA.

14. The non-transitory storage computer-readable medium of claim 12, wherein each of the one or more segments has a constant mechanical property.

15. The non-transitory storage computer-readable medium of claim 14, wherein the one or more instructions, that when executed by the processor, further cause the processor to solve an auxiliary problem for each of the one or more segments using a nonlinear beam equation with two boundary conditions.

16. The non-transitory storage computer-readable medium of claim 15, wherein the two boundary conditions are external loading or confines of the borehole.

17. The non-transitory storage computer-readable medium of claim 16, wherein the external loading is an actuation or a weight-on-bit.

18. The non-transitory storage computer-readable medium of claim 12, wherein the one or more instructions, that when executed by the processor, further cause the processor to solve determine a first distance from the BHA to a first borehole wall of the borehole for one of the one or more segments, determine a first reaction force for the first distance, and solve a mixed complementarity problem (MCP) based at least in part on the first distance, the first reaction force, and a second distance from the BHA to a second borehole wall.

19. The non-transitory storage computer-readable medium of claim 18, wherein the MCP is solved using a Jacobian matrix.

20. The non-transitory storage computer-readable medium of claim 18, wherein the MCP is solved using a Levenberg-Marquardt Mixed Complementarity Problem (LMMCP).
